(19) United States
(12) Patent Application Publication
(10) Pub. No.: US 2016/0276526 A1
(43) Pub. Date: Sep. 22, 2016

(54) SEMICONDUCTOR LIGHT EMITTING DEVICE

(71) Applicant: KABUSHIKI KAISHA TOSHIBA, Tokyo (JP)

(72) Inventors: Koji Kaga, Komatsu Ishikawa (JP); Toshiyuki Oka, Kanazawa Ishikawa (JP); Masakazu Sawano, Nonoichi Ishikawa (JP); Kazuyuki Miyabe, Kanazawa Ishikawa (JP)

(21) Appl. No.: 14/843,443

(22) Filed: Sep. 2, 2015

(30) Foreign Application Priority Data
Mar. 16, 2015 (JP) 2015-052125

(51) Int. Cl. H01L 33/02

(52) U.S. Cl. CPC H01L 33/02

(57) ABSTRACT

According to one embodiment, a semiconductor light emitting device includes a base body, first to sixth semiconductor layers, first to third conductive layers, a structure, and a first insulating layer. The first semiconductor layer and the structure are separated from the base body in a first direction. The second semiconductor layer is provided between the first semiconductor layer and the base body. The third semiconductor layer is provided between the first r and second semiconductor layers. The fourth semiconductor layer is separated from the base body in the first direction. The fifth semiconductor layer is provided between the fourth semiconductor layer and the base body. The sixth semiconductor layer is provided between the fourth and fifth semiconductor layers. The conductive layers are electrically connected with the semiconductor layers. A portion of the first insulating layer is provided between the third and fifth semiconductor layers.

### CROSS-REFERENCE TO RELATED APPLICATIONS

This application is based upon and claims the benefit of priority from Japanese Patent Application No. 2015-052125, filed on Mar. 16, 2015; the entire contents of which are incorporated herein by reference.

### FIELD

Embodiments described herein relate generally to a semiconductor light emitting device.

### BACKGROUND

In semiconductor light emitting devices such as light emitting diodes (LEDs), an improvement in efficiency is required.

### BRIEF DESCRIPTION OF THE DRAWINGS

FIG. 1A and FIG. 1B are schematic views illustrating a semiconductor light emitting device according to a first embodiment;

FIG. 2A and FIG. 2B are schematic perspective views illustrating a portion of the semiconductor light emitting device according to the first embodiment;

FIG. 3 is a schematic cross-sectional view illustrating a portion of the semiconductor light emitting device according to the first embodiment;

FIG. 4A to FIG. 4D are schematic cross-sectional views illustrating, in the order of processes, the method for manufacturing the semiconductor light emitting device according to the first embodiment;

FIG. 5A to FIG. 5C are schematic cross-sectional views illustrating, in the order of processes, the method for manufacturing the semiconductor light emitting device according to the first embodiment;

FIG. 6A to FIG. 6C are schematic cross-sectional views illustrating, in the order of processes, the method for manufacturing the semiconductor light emitting device according to the first embodiment;

FIG. 7A to FIG. 7D are schematic perspective views illustrating portions of other semiconductor light emitting devices according to the first embodiment;

FIG. 8 is a schematic cross-sectional view illustrating a semiconductor light emitting device according to a second embodiment;

FIG. 9 is a schematic cross-sectional view illustrating another semiconductor light emitting device according to the second embodiment; and

FIG. 10 is a schematic cross-sectional view illustrating a semiconductor light emitting device according to a third embodiment.

### DETAILED DESCRIPTION

According to one embodiment, a semiconductor light emitting device includes a base body, first to sixth semiconductor layers, first to third conductive layers, a structure, and a first insulating layer. The first semiconductor layer is separated from the base body in a first direction and includes a first semiconductor film of a first conductivity type. The second semiconductor layer is provided between the first semiconductor layer and the base body and has a second conductivity type. The third semiconductor layer is provided between the first semiconductor layer and the second semiconductor layer. The first conductive layer is electrically connected with the second semiconductor layer. The fourth semiconductor layer is separated from the base body in the first direction, is arranged with the first semiconductor layer in a second direction crossing the first direction, and includes a second semiconductor film of the first conductivity type. The fifth semiconductor layer is provided between the fourth semiconductor layer and the base body and has the second conductivity type. The sixth semiconductor layer is provided between the fourth semiconductor layer and the fifth semiconductor layer. The second conductive layer is electrically connected with the fifth semiconductor layer. The structure is separated from the base body in the first direction, and at least a portion of the structure is provided between the first semiconductor layer and the fourth semiconductor layer. The third conductive layer is electrically connected with the fourth semiconductor layer. The third conductive layer includes a first region, a second region, and a third region between the first region and the second region. At least a portion of the first insulating layer is provided between the third conductive layer and the fifth semiconductor layer. A fourth region of the first conductive layer is provided between the second semiconductor layer and the base body. A fifth region of the first conductive layer is provided between the first region and the base body. The fifth region is electrically connected with the first region. A portion of the fourth semiconductor layer is provided between the second region and the second conductive layer. The structure is provided between the third region and the base body. A thickness of the structure along the first direction is smaller than a distance between the second region and the second conductive layer along the first direction.

According to another embodiment, a semiconductor light emitting device includes a base body, first to sixth semiconductor layers, first to third conductive layers, a first insulating layer. The first semiconductor layer is separated from the base body in a first direction and includes a first semiconductor film of a first conductivity type. The second semiconductor layer is provided between the first semiconductor layer and the base body and has a second conductivity type. The third semiconductor layer is provided between the first semiconductor layer and the second semiconductor layer. The first conductive layer is electrically connected with the second semiconductor layer. The fourth semiconductor layer is separated from the base body in the first direction, is arranged with the first semiconductor layer in a second direction crossing the first direction, and includes a second semiconductor film of the first conductivity type. The fourth semiconductor layer includes a first semiconductor region and a second semiconductor region. The second semiconductor region is provided between at least a portion of the first semiconductor region and at least a portion of the first semiconductor layer. The fifth semiconductor layer is provided between the fourth semiconductor layer and the base body and has the second conductivity type. The sixth semiconductor layer is provided between the fourth semiconductor layer and the fifth semiconductor layer. The second conductive layer is electrically connected with the fifth semiconductor layer. The third conductive layer is electrically connected with the fourth semiconductor layer. The third conductive layer includes a first region, a second region, and a third region between the first region and the second region. At least a portion of the first insulating layer is provided between the third conductive layer and the fifth semiconductor layer. A fourth region of the first conductive layer is provided between the second semiconductor layer and the base body. A fifth region of the first conductive layer is provided between the first region and the base body. The fifth region is electrically connected with the first region. The first semiconductor region is provided between the second region and the second conductive layer. The second semiconductor region is provided between the third region and the base body. A total thickness of the second semiconductor region, the fifth semiconductor layer, and the sixth semiconductor layer is smaller than a distance between the second region and the second conductive layer along the first direction.

Various embodiments will be described hereinafter with reference to the accompanying drawings.

The drawings are schematic or conceptual. The relationship between the thickness and the width of each portion, the size ratio between the portions, and the like are not necessarily the same as the actual values thereof. Moreover, the dimension or the ratio may be shown differently depending on the drawings, even for identical portions.

In the specification of the application and the drawings, components similar to those described previously with reference to earlier drawings are marked with like reference numerals, and the detailed description thereof is omitted as appropriate.

### First Embodiment

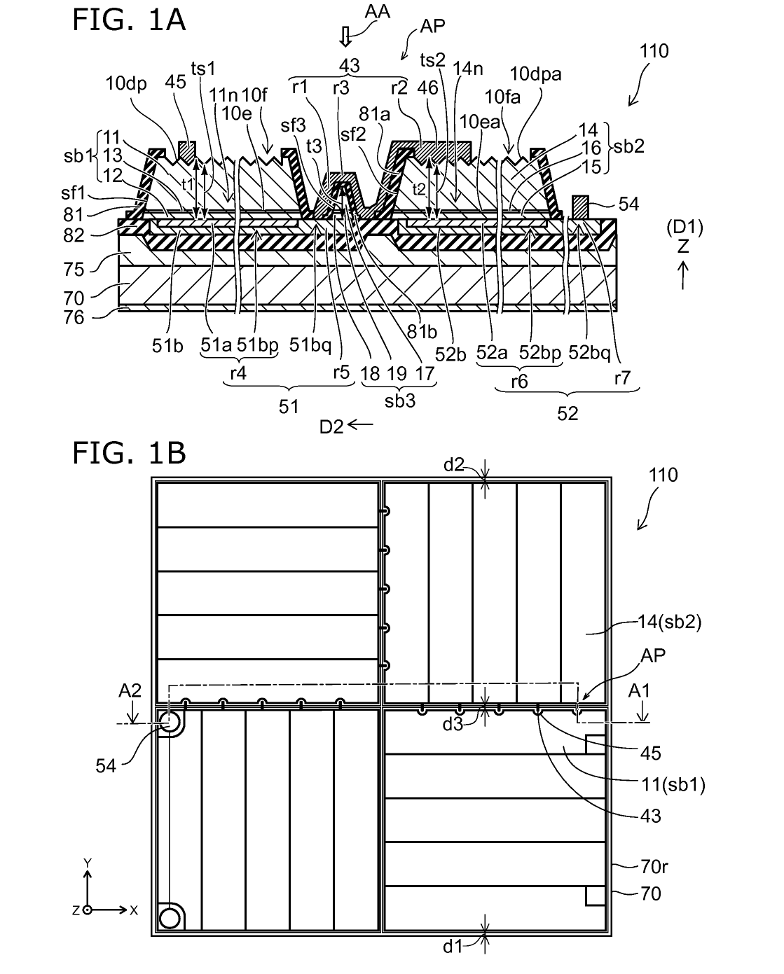

FIG. 1A and FIG. 1B are schematic views illustrating a semiconductor light emitting device according to a first embodiment.

FIG. 1A is a cross-sectional view taken along the line A1-A2 in FIG. 1B. FIG. 1B is a plan view as viewed in the direction of the arrow AA shown in FIG. 1A. In FIG. 1B, some portions in a state of being viewed in a see-through manner are shown by a broken line. A portion AP shown in FIG. 1A corresponds to a portion AP shown in FIG. 1B.

As shown in FIG. 1A and FIG. 1B, the semiconductor light emitting device 110 according to the embodiment includes a base body 70, first to sixth semiconductor layers 11 to 16, a first conductive layer 51, a second conductive layer 52, a structure sb3, a third conductive layer 43, and a first insulating layer 81a.

As the base body 70, for example, a semiconductor substrate of Si or the like is used. An example of the base body 70 will be described later.

The first semiconductor layer 11 is separated from the base body 70 in a first direction D1. The first direction D1 is a direction from the base body 70 toward the first semiconductor layer 11. The first semiconductor layer 11 includes a first semiconductor film 11n of a first conductivity type. An example of the first semiconductor film 11n will be described later.

The first direction D1 is defined as a Z-axis direction. One direction perpendicular to the Z-axis direction is defined as an X-axis direction. A direction perpendicular to the Z-axis direction and the X-axis direction is defined as a Y-axis direction.

The second semiconductor layer 12 is provided between the first semiconductor layer 11 and the base body 70. The second semiconductor layer 12 is of a second conductivity type. For example, the first conductivity type is n-type, and the second conductivity type is p-type. The first conductivity type may be p-type, and the second conductivity type may be n-type. In the following example, the first conductivity type is n-type, and the second conductivity type is p-type.

The third semiconductor layer 13 is provided between the first semiconductor layer 11 and the second semiconductor layer 12. The first semiconductor layer 11, the second semiconductor layer 12, and the third semiconductor layer 13 are included in a first stacked body sb1. The first stacked body sb1 extends along an X-Y plane.

The first conductive layer 51 is electrically connected with the second semiconductor layer 12. A portion of the first conductive layer 51 is provided between the second semiconductor layer 12 and the base body 70.

In the specification, an electrically connected state includes a state in which a first conductor and a second conductor are in direct contact with each other. Further, the electrically connected state includes a state in which a third conductor is inserted between the first conductor and the second conductor and a current flows between the first conductor and the second conductor via the third conductor.

At least a portion of the first conductive layer 51 is in ohmic contact with the second semiconductor layer 12. The first conductive layer 51 is, for example, light-reflective. The fourth semiconductor layer 14 is separated from the base body 70 in the first direction D1. The fourth semiconductor layer 14 is arranged with the first semiconductor layer 11 in a second direction D2. The second direction D2 crosses the first direction D1.

In the portion AP shown in FIG. 1A and FIG. 1B, the second direction D2 is, for example, the Y-axis direction. The fourth semiconductor layer 14 includes a second semiconductor film 14n of the first conductivity type. An example of the second semiconductor film 14n will be described later.

The fifth semiconductor layer 15 is provided between the fourth semiconductor layer 14 and the base body 70. The sixth semiconductor layer 16 is provided between the fourth semiconductor layer 14 and the fifth semiconductor layer 15. The fourth semiconductor layer 14, the fifth semiconductor layer 15, and the sixth semiconductor layer 16 are included in a second stacked body sb2. The second stacked body sb2 extends along the X-Y plane.

The second conductive layer 52 is electrically connected with the fifth semiconductor layer 15. A portion of the second conductive layer 52 is provided between the fifth semiconductor layer 15 and the base body 70.

The third semiconductor layer 13 and the sixth semiconductor layer 16 include, for example, an active layer. The third semiconductor layer 13 and the sixth semiconductor layer 16 are, for example, light emitting portions. Examples of the third semiconductor layer 13 and the sixth semiconductor layer 16 will be described later.

The first to sixth semiconductor layers 11 to 16 include, for example, a nitride semiconductor. Examples of these semiconductor layers will be described later.

The structure sb3 is separated from the base body 70 in the first direction D1. At least a portion of the structure sb3 is provided between at least a portion of the first stacked body sb1 and at least a portion of the second stacked body sb2. At least a portion of the structure sb3 is provided, for example, between the first semiconductor layer 11 and the fourth semiconductor layer 14. At least a portion of the structure sb3 may be provided between the second semiconductor layer 12 and the fifth semiconductor layer 15. At least a portion of the structure sb3 may be provided between the third semiconductor layer 13 and the sixth semiconductor layer 16.

The third conductive layer 43 is electrically connected with the fourth semiconductor layer 14. The third conductive layer 43 is electrically connected with the second semiconductor film 14n. As will be described later, the third conductive layer 43 is also connected with the second semiconductor layer 12. For example, the first stacked body sb1 is, for example, a first LED. The second stacked body sb2 is, for example, a second LED. The second semiconductor layer 12 is, for example, a p-type semiconductor layer, and the fourth semiconductor layer 14 is, for example, an n-type semiconductor layer. The third conductive layer 43 electrically connects the p-type semiconductor layer of the first LED with the n-type semiconductor layer of the second LED. The first LED and the second LED are connected in series.

The third conductive layer 43 includes first to third regions r1 to r3. The third region r3 is provided between the first region r1 and the second region r2.

The first region r1 is electrically connected with the second semiconductor layer 12 via the first conductive layer 51.

The second region r2 is electrically connected with the fourth semiconductor layer 14. Specifically, the second region r2 is electrically connected with the second semiconductor film 14n. In this example, a sixth conductive layer 46 that is continuous with the second region r2 is provided. The fourth semiconductor layer 14 is disposed between the sixth conductive layer 46 and the sixth semiconductor layer 16. The sixth conductive layer 46 is continuous with the second region r2.

At least a portion of the first insulating layer 81a is provided between the third conductive layer 43 and the fifth semiconductor layer 15. At least a portion of the first insulating layer 81a may be provided between the third conductive layer 43 and the sixth semiconductor layer 16. The first insulating layer 81a electrically insulates the third conductive layer 43 from the fifth semiconductor layer 15. The first insulating layer 81a electrically insulates the third conductive layer 43 from the sixth semiconductor layer 16.

The first conductive layer 51 includes a fourth region r4 and a fifth region r5. The fourth region r4 is provided between the second semiconductor layer 12 and the base body 70. The fifth region r5 is provided between the first region r1 of the third conductive layer 43 and the base body 70. The fifth region r5 is electrically connected with the first region r1.

A portion of the fourth semiconductor layer 14 is provided between the second region r2 of the third conductive layer 43 and the base body 70. In this example, a portion of the fourth semiconductor layer 14 is provided between the second region r2 of the third conductive layer 43 and the second conductive layer 52. That is, the second region r2 extends over a portion of the fourth semiconductor layer 14.

The structure sb3 is provided between the third region r3 of the third conductive layer 43 and the base body 70. That is, the third conductive layer 43 extends between a region on the fifth region r5 of the first conductive layer 51 and a region on a portion of the fourth semiconductor layer 14, and a middle portion (the third region r3) of the third conductive layer 43 is provided above the structure sb3. An insulating layer 81b is provided between the third region r3 of the third conductive layer 43 and the structure sb3.

In the embodiment, a thickness t3 of the structure sb3 along the first direction D1 is smaller than a distance t2 between the second region r2 and the second conductive layer 52 along the first direction D1. The distance t2 corresponds to the thickness of the second stacked body sb2 along the first direction D1. The thickness t3 is thinner than a total thickness (i.e., the distance t2) of the fourth semiconductor layer 14, the sixth semiconductor layer 16, and the fifth semiconductor layer 15.

That is, the height of the structure sb3 is lower than the height of the second stacked body sb2 based on, for example, the base body 70.

The third conductive layer 43 serves as a wiring layer by means of which the first LED and the second LED are connected in series. The third conductive layer 43 includes a portion which extends between a height position (position along the first direction D1) of the upper surface of the first conductive layer 51 and a height position (position along the first direction D1) of the upper surface of the second stacked body sb2.

In this case, in the embodiment, the third conductive layer 43 reaches the upper surface of the fourth semiconductor layer 14 by way of the structure sb3 with a low height. The middle portion (the third region r3) of the third conductive layer 43 is provided above the structure sb3. For this reason, a sharp change in a step is suppressed. For this reason, for example, disconnection of the third conductive layer 43 due to the step is suppressed.

For example, there is a reference example in which the structure sb3 is not provided. In this reference example, the third conductive layer 43 extends along the side surface of a large step caused by the second stacked body sb2. At this step portion, the disconnection of the third conductive layer 43 is likely to occur. For this reason, an electrical connection becomes unstable. It is conceivable for obtaining a reliable connection to, for example, increase the gap between the plurality of LEDs, but this reduces a light emission area in the entire area of the device, so that luminous efficiency is reduced.

In contrast, in the embodiment, the structure sb3 is provided, and the third conductive layer 43 is configured so as to pass above the structure sb3. Due to this, a step to be produced is small compared to the reference example described above. Due to this, the disconnection of the third conductive layer 43 is suppressed, so that the electrical connection becomes stable. For this reason, design tolerance taking the disconnection into consideration is increased. For example, the gap between the plurality of LEDs can be reduced, so that the luminous efficiency can be improved. Further, high reliability is obtained. Further, yield is improved, so that high productivity is obtained.

According to the embodiment, it is possible to provide a semiconductor light emitting device capable of improving efficiency.

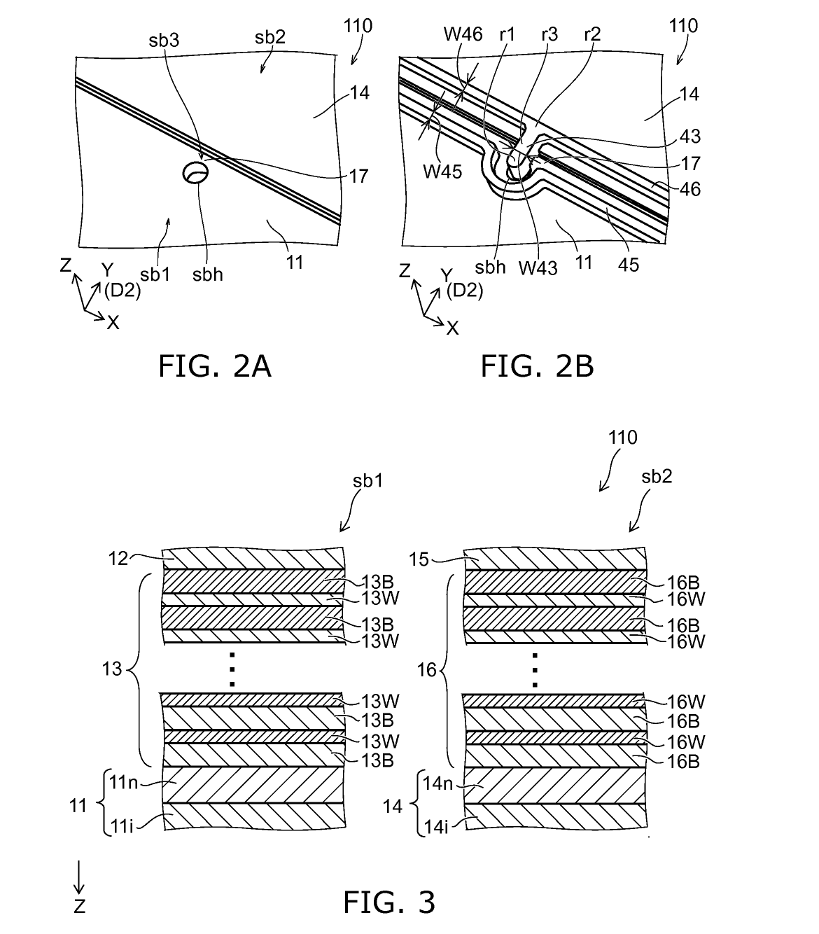

FIG. 2A and FIG. 2B are schematic perspective views illustrating a portion of the semiconductor light emitting device according to the first embodiment.

These drawings show, in an enlarged manner, the portion AP shown in FIG. 1B. FIG. 2A illustrates a state in which a fifth conductive layer 45 is removed for the clarity of the drawing. In these drawings, the insulating layer is omitted.

As shown in FIG. 2A, the structure sb3 is provided between the first stacked body sb1 and the second stacked body sb2. In this example, a hole sbh is provided in a semiconductor stacked film serving as the first stacked body sb1. A portion of the semiconductor stacked film between the hole sbh and the second stacked body sb2 serves as the structure sb3.

As shown in FIG. 2B, the fifth conductive layer 45 is provided on the semiconductor stacked film partially around the hole sbh. One end (the first region r1) of the third conductive layer 43 is provided in the hole sbh. The third region r3 of the third conductive layer 43 is provided on the semiconductor stacked film (the structure sb3) located between the hole sbh and the fourth semiconductor layer 14. The second region r2 of the third conductive layer 43 is provided on the fourth semiconductor layer 14. A sixth conductive layer 46 is connected to the second region r2 of the third conductive layer 43.

In this manner, the structure sb3 may be continuous with the first stacked body sb1.

In the embodiment, the semiconductor serving as the first stacked body sb1 and the second stacked body sb2 may be used for the structure sb3.

That is, in the semiconductor light emitting device 110, the structure sb3 includes seventh to ninth semiconductor layers 17 to 19. The seventh semiconductor layer 17 is of the first conductivity type. The eighth semiconductor layer 18 is provided between the seventh semiconductor layer 17 and the base body 70. The eighth semiconductor layer 18 is of the second conductivity type. The ninth semiconductor layer 19 is provided between the seventh semiconductor layer 17 and the eighth semiconductor layer 18. The seventh to ninth semiconductor layers 17 to 19 include, for example, a nitride semiconductor.

The structure sb3 can be formed together with the first stacked body sb1 and the second stacked body sb2. Due to this, high productivity is obtained. An example of a method for manufacturing the semiconductor light emitting device 110 will be described later.

For example, the semiconductor light emitting device 110 may include the base body 70, the first stacked body sb1, the second stacked body sb2, the first conductive layer 51, the second conductive layer 52, the third conductive layer 43, and the first insulating layer 81a. The first stacked body sb1 includes the first to third semiconductor layers 11 to 13. The second stacked body sb2 includes the fourth to sixth semiconductor layers 14 to 16. The first stacked body sb1 includes the hole sbh. The first stacked body sb1 includes the portion (the structure sb3) between the hole sbh and the second stacked body sb2. The first stacked body sb1 includes the structure sb3 and a portion different from the structure sb3. The hole sbh is provided between the different portion and the structure sb3. The first conductive layer 51 is electrically connected with the second semiconductor layer 12. The second conductive layer 52 is electrically connected with the fifth semiconductor layer 15. The third conductive layer 43 is electrically connected with the fourth semiconductor layer 14. The third conductive layer 43 includes the first region r1, the second region r2, and the third region r3 between the first region r1 and the second region r2. At least a portion of the first insulating layer 81a is provided between the third conductive layer 43 and the fifth semiconductor layer 15. The fourth region r4 of the first conductive layer 51 is provided between the second semiconductor layer 12 and the base body 70. The fifth region r5 of the first conductive layer 51 is provided between the first region r1 and the base body 70, and the fifth region r5 is electrically connected with the first region r1. A portion of the fourth semiconductor layer 14 is provided between the second region r2 and the second conductive layer 52. The portion (the structure sb3) between the hole sbh and the second stacked body sb2 is provided between the third region r3 and the base body 70. The thickness t3 of the portion (the structure sb3) between the hole sbh and the second stacked body sb2 along the first direction D1 is smaller than the distance between the second region r2 and the second conductive layer 52 along the first direction D1.

The side surfaces of the first stacked body sb1 and the second stacked body sb2 are favorably inclined. Due to this, the coverage of the third conductive layer 43 is improved, so that a more stable connection is obtained.

That is, the first stacked body sb1 including the first semiconductor layer 11, the third semiconductor layer 13, and the second semiconductor layer 12 includes a side surface sf1. The side surface sf1 crosses the second direction D2, and is inclined to the first direction D1. An angle between the side surface sf1 and the X-Y plane is, for example, 30 degrees or more and 80 degrees or less.

On the other hand, the second stacked body sb2 including the fourth semiconductor layer 14, the sixth semiconductor layer 16, and the fifth semiconductor layer 15 includes a side surface sf2. The side surface sf2 crosses the second direction D2, and is inclined to the first direction D1. An angle between the side surface sf2 and the X-Y plane is, for example, 30 degrees or more and 80 degrees or less.

In this example, the first insulating layer 81a extends between the third conductive layer 43 and the side surface sf2 of the second stacked body sb2. The first insulating layer 81a covers the side surface sf2 of the second stacked body sb2.

Also the side surface of the structure sb3 is favorably inclined. That is, the structure sb3 includes a side surface sf3. The side surface sf3 crosses the second direction D2, and is inclined to the first direction D1. The coverage of the third conductive layer 43 is improved, so that a more stable connection is obtained.

The thickness t3 is favorably ⅕ times or more and ⅔ times or less the distance t2. When the thickness t3 is excessively thin, the disconnection of the third conductive layer 43 may be likely to occur between the structure sb3 and the fourth semiconductor layer 14. When the thickness t3 is excessively thick, the disconnection of the third conductive layer 43 may be likely to occur between the first conductive layer 51 and the structure sb3.

In this example, a fourth conductive layer 54 and the fifth conductive layer 45 are provided. When the fifth semiconductor layer 15 is of p-type, the fourth conductive layer 54 serves as a p-side pad. When the first semiconductor layer 11 is of n-type, the fifth conductive layer 45 serves as an n-side pad.

A portion of the second conductive layer 52 is disposed between the fourth conductive layer 54 and the base body 70. The fourth conductive layer 54 is electrically connected with the portion of the second conductive layer 52. That is, the second conductive layer 52 includes a sixth region r6 and a seventh region r7. The sixth region r6 is provided between the fifth semiconductor layer 15 and the base body 70. The seventh region r7 is disposed between the fourth conductive layer 54 and the base body 70. The fourth conductive layer 54 is electrically connected with the seventh region r7.

The first semiconductor layer 11 is disposed between the fifth conductive layer 45 and the base body 70. The fifth conductive layer 45 is electrically connected with the first semiconductor film 11n of the first semiconductor layer 11.

In this example, each of the first conductive layer 51 and the second conductive layer 52 includes a plurality of metal layers.

The first conductive layer 51 includes a first metal layer 51a and a second metal layer 51b. The first metal layer 51a is provided between the second semiconductor layer 12 and the base body 70. A first portion 51bp of the second metal layer 51b is provided between the first metal layer 51a and the base body 70. A second portion 51bq of the second metal layer 51b is provided between the first region r1 of the third conductive layer 43 and the base body 70.

The first portion 51bp of the second metal layer 51b and the first metal layer 51a are included in the fourth region r4 of the first conductive layer 51. The second portion 51bq of the second metal layer 51b is included in the fifth region r5 of the first conductive layer 51.

On the other hand, the second conductive layer 52 includes a third metal layer 52a and a fourth metal layer 52b. The third metal layer 52a is provided between the fifth semiconductor layer 15 and the base body 70. A portion (third portion 52bp) of the fourth metal layer 52b is provided between the third metal layer 52a and the base body 70. A portion (fourth portion 52bq) of the fourth metal layer 52b is disposed between the fourth conductive layer 54 and the base body 70. The fourth conductive layer 54 is electrically connected with the fourth portion 52bq.

The third portion 52bp of the fourth metal layer 52b and the third metal layer 52a are included in the sixth region r6 of the second conductive layer 52. The fourth portion 52bq of the fourth metal layer 52b is included in the seventh region r7 of the second conductive layer 52.

In the embodiment, the second conductive layer 52 may include a semiconductor layer (e.g., a nitride semiconductor layer). For example, a third LED may be provided between the second LED and the fourth conductive layer 54 (e.g., a p-side pad), the second LED and the third LED may be connected in series, and the third LED and the p-side pad may be connected with each other. In this case, the third LED can be regarded as a portion of the second conductive layer 52. For example, the third LED may be regarded as a portion of an interconnection (conductive layer) provided between the sixth region r6 and the seventh region r7.

For example, a voltage is applied between the fourth conductive layer 54 and the fifth conductive layer 45. Through these conductive layers, a current is supplied to the first LED and the second LED. Light is emitted from the third semiconductor layer 13 and the sixth semiconductor layer 16.

The light (emitted light) emitted from the third semiconductor layer 13 is reflected by the first conductive layer 51, and exits to the outside of the semiconductor light emitting device 110. The surface of the first semiconductor layer 11 serves as a light exiting face. The light (emitted light) emitted from the sixth semiconductor layer 16 is reflected by the second conductive layer 52, and exits to the outside of the semiconductor light emitting device 110. The surface of the fourth semiconductor layer 14 serves as a light exiting face.

In this example, corrugation 10dp are provided on the light exiting face of the first semiconductor layer 11, and corrugation 10dpa are provided on the light exiting face of the fourth semiconductor layer 14.

That is, the first semiconductor layer 11 includes a first face 10e and a second face 10f. The first face 10e is a face on the side of the third semiconductor layer 13. The first face 10e faces the third semiconductor layer 13. The second face 10f is a face on the side opposite to the first face 10e. The second face 10f serves as the light exiting face. The corrugation 10dp is provided on the second face 10f. By providing the corrugation 10dp, light can be efficiently extracted from the first stacked body sb1.

The fourth semiconductor layer 14 includes a third face 10ea and a fourth face 10fa. The third face 10ea is a face on the side of the sixth semiconductor layer 16. The third face 10ea faces the sixth semiconductor layer 16. The fourth face 10fa is a face on the side opposite to the third face 10ea. The fourth face 10fa serves as the light exiting face. The corrugation 10dpa is provided on the fourth face 10fa. By providing the corrugation 10dpa, light can be efficiently extracted from the second stacked body sb2.

The height (depth) of each of the corrugation 10dp and the corrugation 10dpa is, for example, 0.5 times or more and 30 times or less a peak wavelength. The height (depth) of each of the corrugation 10dp and the corrugation 10dpa is, for example, 0.4 micrometer (μm) or more and 2 μm or less. The width of the top of each of the corrugation 10dp and the corrugation 10dpa in a direction (e.g., may be the second direction D2) perpendicular to the first direction D1 is, for example, 0.5 times or more and 30 times or less the peak wavelength. The intensity of the light emitted from the third semiconductor layer 13 and the sixth semiconductor layer 16 reaches substantially its peak (maximum) at the peak wavelength. The corrugation 10dp has, for example, a truncated cone shape. The diameter of the top of the convex portion of the corrugation 10dp is appropriately 1.5 μm or more and 2.5 μm or less. The diameter of the bottom of the convex portion of the corrugation 10dp is, for example, appropriately 1.5 μm or more and 4.0 μm or less. The height of the convex portion is, for example, appropriately 1 μm or more and 2 μm or less. The pitch of a plurality of the convex portions is, for example, appropriately 3 μm or more and 7 μm or less.

For example, the semiconductor light emitting device 110 is a thin film type LED. As will be described later, in the semiconductor light emitting device 110, crystal of the first stacked body sb1 and the second stacked body sb2 is grown on a growth substrate, and thereafter, the first stacked body sb1 and the second stacked body sb2 are bonded to the base body 70. Then, the growth substrate is removed. The growth substrate is thick, and the heat capacity of the growth substrate is large. In the semiconductor light emitting device 110, since the growth substrate is removed, the heat capacity of the semiconductor light emitting device 110 can be reduced, so that heat dissipation property can be enhanced.

In the semiconductor light emitting device 110, since the growth substrate is removed, a distance between the upper surface (light exiting face, i.e., the second face 10f) of the first semiconductor layer 11 and the first conductive layer 51 is short. Similarly, a distance between the upper surface (light exiting face, i.e., the fourth face 10fa) of the fourth semiconductor layer 14 and the second conductive layer 52 is short.

For example, a distance t1 between the first conductive layer 51 and the second face 10f of the first semiconductor layer 11 is 1.5 μm or more and 30 μm or less. The distance (corresponding to the distance t2) between the second conductive layer 52 and the fourth face 10fa of the fourth semiconductor layer 14 is 1.5 μm or more and 30 μm or less.

When the corrugation 10dp is provided on the second face 10f of the first semiconductor layer 11, the configuration is as follows. For example, the distance t1 is the longest distance between the first conductive layer 51 and the second face 10f along the first direction D1. When the corrugation 10dp is provided, the distance t1 corresponds to the longest distance between the top of the corrugation 10dp and the first conductive layer 51 along the first direction D1. The distance t1 corresponds to the thickness of the first stacked body sb1 along the first direction D1. When the corrugation 10dp are provided, the distance t1 corresponds to the maximum value of the thickness of the first stacked body sb1 along the first direction D1.

When the corrugation 10dp are provided on the second face 10f of the first semiconductor layer 11, the shortest distance (shortest distance ts1) between the first conductive layer 51 and the second face 10f along the first direction D1 can be defined. The shortest distance ts1 corresponds to the shortest distance between the bottom of the corrugation 10dp and the first conductive layer 51 along the first direction D1. The shortest distance ts1 corresponds to the minimum value of the thickness of the first stacked body sb1 along the first direction D1. When the corrugation 10dp are provided, the shortest distance ts1 corresponds to the minimum value of the thickness of the first stacked body sb1 along the first direction D1.

When the corrugation 10dpa is provided on the fourth face 10fa of the fourth semiconductor layer 14, the configuration is as follows. For example, the distance t2 is the longest distance between the second conductive layer 52 and the fourth face 10fa along the first direction D1. When the corrugation 10dpa is provided, the distance t2 corresponds to the longest distance between the top of the corrugation 10dpa and the second conductive layer 52 along the first direction D1. The distance t2 corresponds to the thickness of the second stacked body sb2 along the first direction D1. When the corrugation 10dpa are provided, the distance t2 corresponds to the maximum value of the thickness of the second stacked body sb2 along the first direction D1.

When the corrugation 10dpa are provided on the second face 10fa of the fourth semiconductor layer 14, the shortest distance (shortest distance ts2) between the second conductive layer 52 and the fourth face 10fa along the first direction D1 can be defined. The shortest distance ts2 corresponds to the shortest distance between the bottom of the corrugation 10dpa and the second conductive layer 52 along the first direction D1. The shortest distance ts2 corresponds to the minimum value of the thickness of the second stacked body sb2 along the first direction D1. When the corrugation 10dpa are provided, the shortest distance ts2 corresponds to the minimum value of the thickness of the second stacked body sb2 along the first direction D1.

As has been described above, the thickness t3 is smaller than the distance t2. When the corrugation 10dp are provided, the thickness t3 is smaller than the maximum value of the thickness of the second stacked body sb2 along the first direction D1. In the embodiment, the thickness t3 may be the same as the shortest distance ts2. Alternatively, the thickness t3 may be smaller than the shortest distance ts2.

In the embodiment, the distance t2 may be set to be substantially the same as the distance t1. The shortest distance ts2 may be set to be substantially the same as the shortest distance ts1. Hence, the thickness t3 is smaller than the distance t1. When the corrugation 10dp are provided, the thickness t3 is smaller than the maximum value of the thickness of the first stacked body sb1 along the first direction D1. In the embodiment, the thickness t3 may be the same as the shortest distance ts1. Alternatively, the thickness t3 may be smaller than the shortest distance ts1.

In this example, an insulating layer 81 is further provided. The insulating layer 81 covers the side surface sf1 of the first stacked body sb1.

In this example, the semiconductor light emitting device 110 further includes a second insulating layer 82. The second insulating layer 82 is provided between the first conductive layer 51 and the base body 70, and between the second conductive layer 52 and the base body 70. With the second insulating layer 82, the first conductive layer 51 and the base body 70 are insulated from each other, and the second conductive layer 52 and the base body 70 are insulated from each other. This enables a series connection while using the base body 70 that is conductive.

The base body 70 is, for example, conductive. For the base body 70, for example, a semiconductor such as Si, or a conductor such as metal is used. Due to this, high heat dissipation property is obtained in the base body 70.

The second insulating layer 82 insulates the first conductive layer 51 from the base body 70. The second insulating layer 82 insulates the second conductive layer 52 from the base body 70. These conductive layers can be insulated from the base body 70 while obtaining high heat dissipation property by using the conductive base body 70. The first conductive layer 51 and the second conductive layer 52 are insulated from each other with the second insulating layer 82. Due to this, the series connection of the two LEDs is obtained.

In this example, the semiconductor light emitting device 110 further includes a fifth metal layer 75. The fifth metal layer 75 is provided between the second insulating layer 82 and the base body 70. The fifth metal layer 75 bonds, for example, the second insulating layer 82 with the base body 70. The fifth metal layer 75 is, for example, a bonding metal layer.

In this example, the semiconductor light emitting device 110 further includes a sixth metal layer 76. The base body 70 is disposed between the second insulating layer 82 and the sixth metal layer 76. That is, the base body 70 is disposed between the fifth metal layer 75 and the sixth metal layer 76. The sixth metal layer 76 is connected to, for example, a mounting board (not shown) or the like. For this connection, for example, solder or the like is used. By providing the sixth metal layer 76, a stable connection is obtained. High heat dissipation property is obtained.

For the sixth metal layer 76, for example, a stacked film of Al film (with a thickness of 300 nm or more and 500 nm or less, e.g., about 380 nm)/Ti film (with a thickness of 30 nm or more and 100 nm or less, e.g., about 50 nm)/Ni film (with a thickness of 30 nm or more and 100 nm or less, e.g., about 50 nm)/AuAg film (with a thickness of 10 nm or more and 50 nm or less, e.g., about 30 nm) is used.

The insulating layer 81 and the first insulating layer 81a include, for example, silicon oxide, silicon nitride, or silicon oxynitride. By providing these insulating layers, a current flowing through the side surface sf1 of the first stacked body sb1 and the side surface sf2 of the second stacked body sb2 can be suppressed, so that the breakdown voltage can be improved. Then, high reliability is obtained. These insulating layers are formed by, for example, plasma chemical vapor deposition (CVD) or the like.

The second insulating layer 82 includes, for example, a first layer, a second layer, and a third layer. The second layer is provided between the first layer and the base body 70. The third layer is provided between the second layer and the base body 70. The first layer and the third layer include, for example, silicon oxide. The second layer includes, for example, silicon nitride. The second insulating layer 82 has, for example, a stacked structure of SiO₂/SiNₓ/SiO₂. Due to this, high insulating property is obtained.

The first metal layer 51a and the third metal layer 52a include, for example, at least any of silver and rhodium. The first metal layer 51a and the third metal layer 52a may include a silver alloy. As the first metal layer 51a and the third metal layer 52a, for example, a silver layer, a rhodium layer, or a silver alloy layer is used. Due to this, a high light reflectance is obtained. A low contact resistance is obtained between the first metal layer 51a and the second semiconductor layer 12 and between the third metal layer 52a and the fifth semiconductor layer 15. The first metal layer 51a and the third metal layer 52a may include aluminum.

The thickness of each of the first metal layer 51a and the third metal layer 52a is, for example, 50 nm or more and 500 nm or less.

Each of the second metal layer 51b and the fourth metal layer 52b includes, for example, at least any of Ni, Pt, Au, and Ti. Each of the second metal layer 51b and the fourth metal layer 52b includes, for example, a Ni-containing region, a Pt-containing region, an Au-containing region, and a Ti-containing region.

In the second metal layer 51b, the Au-containing region is provided between the Ti-containing region and the first metal layer 51a. The Pt-containing region is provided between the Au-containing region and the first metal layer 51a. The Ni-containing region is provided between the Pt-containing region and the first metal layer 51a.

In the fourth metal layer 52b, the Au-containing region is provided between the Ti-containing region and the third metal layer 52a. The Pt-containing region is provided between the Au-containing region and the third metal layer 52a. The Ni-containing region is provided between the Pt-containing region and the third metal layer 52a.

The second metal layer 51b and the fourth metal layer 52b are, for example, reflective. The second metal layer 51b and the fourth metal layer 52b may include at least any of silver and aluminum.

The thickness of each of the second metal layer 51b and the fourth metal layer 52b is, for example, 300 nm or more and 1500 nm or less.

To the fourth conductive layer 54, for example, a stacked structure including an Al film, a Ti film, a Pt film, and an Au film is applied. The Al film is provided on the first semiconductor layer 11, and the Ti film, the Pt film, and the Au film are provided in this order on the Al film. To the fourth conductive layer 54, for example, a stacked structure including an Al film, a Ti film, a Pt film, and an Au film is applied. The Al film is provided on a portion (the seventh region r7) of the second conductive layer 52, and the Ti film, the Pt film, and the Au film are provided in this order on the Al film.

The thickness of the Al film is, for example, about 3 μm (e.g., 2 μm or more and 4 μm or less). The thickness of the Ti film is, for example, about 100 nm (e.g., 50 nm or more and 200 nm or less). The thickness of the Pt film is, for example, about 100 nm (e.g., 50 nm or more and 200 nm or less). The thickness of the Au film is, for example, about 1 μm (e.g., 0.5 μm or more and 1.5 μm or less).

As shown in FIG. 1B, a distance d3 (distance along the X-Y plane) between the first semiconductor layer 11 and the fourth semiconductor layer 14 is narrower than a distance d1 (distance along the X-Y plane) between an outer edge 70r of the base body 70 and the first semiconductor layer 11. The distance d3 is narrower than a distance d2 (distance along the X-Y plane) between the outer edge 70r of the base body 70 and the fourth semiconductor layer 14. That is, the distance (distance d3) between the first semiconductor layer 11 and the fourth semiconductor layer 14 is narrower than the distance (distance d1) between the outer edge of a chip and the first semiconductor layer 11, and narrower than the distance (distance d2) between the outer edge of the chip and the fourth semiconductor layer 14. By narrowing the gap between the plurality of light emitting portions (LEDs), luminous efficiency can be improved.

As shown in FIG. 1B, a plurality of the structures sb3 may be provided between the first stacked body sb1 (the first semiconductor layer 11) and the second stacked body sb2 (the fourth semiconductor layer 14). A plurality of the third conductive layers 43 may be provided corresponding to the plurality of structures sb3. Due to this, a plurality of LEDs can be more stably connected with each other. The connection of low resistance becomes possible.

As shown in FIG. 2B, a width w43 (line width along a direction orthogonal to the second direction D2 in which the third conductive layer 43 extends) of the third conductive layer 43 is wider than a width w45 (line width along a direction orthogonal to the direction in which the fifth conductive layer 45 extends) of the fifth conductive layer 45. The width w43 of the third conductive layer 43 is wider than a width w46 (line width along a direction orthogonal to the direction in which the sixth conductive layer 46 extends) of the sixth conductive layer 46. Due to this, the resistance of connection of the plurality of LEDs can be reduced.

FIG. 3 is a schematic cross-sectional view illustrating a portion of the semiconductor light emitting device according to the first embodiment. FIG. 3 illustrates the first stacked body sb1 and the second stacked body sb2.

As shown in FIG. 3, the third semiconductor layer 13 includes a plurality of barrier layers 13B and well layers 13W provided between the plurality of barrier layers 13B. For example, the plurality of barrier layers 13B and the plurality of well layers 13W are alternately arranged along the Z-axis direction.

Similarly, the sixth semiconductor layer 16 includes a plurality of barrier layers 16B and well layers 16W provided between the plurality of barrier layers 16B. For example, the plurality of barrier layers 16B and the plurality of well layers 16W are alternately arranged along the Z-axis direction.

The well layer includes, for example, Alₓ₁Ga₁₋ₓ₁₋ₓ₂Inₓ₂N (0≦x1≦1, 0≦x2≦1, x1+x2≦1). The barrier layer includes Al_{y1}Ga_{1-y1-y2}In_{y2}N (0≦y1≦1, 0≦y2≦1, y1+y2≦1). A band gap energy in the barrier layer is larger than a band gap energy in the well layer.

For example, the third semiconductor layer 13 and the sixth semiconductor layer 16 have a multi quantum well (MQW) configuration. The third semiconductor layer 13 and the sixth semiconductor layer 16 may have a single quantum well (SQW) configuration.

The peak wavelength of the light (emitted light) emitted from the third semiconductor layer 13 and the sixth semiconductor layer 16 is, for example, 210 nanometer (nm) or more and 780 nm or less. In the embodiment, any peak wavelength may be employed.

In this example, the first semiconductor layer 11 includes the first semiconductor film 11n of the first conductivity type (e.g., an n-type semiconductor layer) and a low impurity concentration region 11i. The first semiconductor film 11n is provided between the third semiconductor layer 13 and the low impurity concentration region 11i. Similarly, the fourth semiconductor layer 14 includes the second semiconductor film 14n of the first conductivity type (e.g., an n-type semiconductor layer) and a low impurity concentration region 14i. The second semiconductor film 14n is provided between the sixth semiconductor layer 16 and the low impurity concentration region 14i. An impurity concentration in the low impurity concentration regions 11i and 14i is lower than an impurity concentration in the first semiconductor film 11n, and lower than an impurity concentration in the second semiconductor film 14n. The impurity concentration in the low impurity concentration regions 11i and 14i is, for example, 1×10¹⁷ cm⁻³ or less.

For the first semiconductor film 11n and the second semiconductor film 14n, for example, a GaN layer including an n-type impurity is used. For the n-type impurity, at least any of Si, O, Ge, Te, and Sn is used. The first semiconductor film 11n and the second semiconductor film 14n include, for example, an n-side contact layer.

For the low impurity concentration regions 11i and 14i, for example, an undoped GaN layer is used. The low impurity concentration regions 11i and 14i may include an Al-containing nitride semiconductor (AlGaN or AlN). These GaN layer, AlGaN layer, and AlN layer may include, for example, a buffer layer used in the crystal growth of the semiconductor layer.

For the second semiconductor layer 12 and the fifth semiconductor layer 15, for example, a GaN layer including a p-type impurity is used. For the p-type impurity, at least any of Mg, Zn, and C is used. The second semiconductor layer 12 and the fifth semiconductor layer 15 include, for example, a p-side contact layer.

The thickness of each of the first semiconductor film 11n and the second semiconductor film 14n is, for example, 500 nm or more and 2000 nm or less.

The thickness of each of the low impurity concentration regions 11i and 14i is, for example, 1000 nm or more and 3000 nm or less.

The thickness of each of the first semiconductor layer 11 and the fourth semiconductor layer 14 is, for example, 500 nm or more and 4000 nm or less.

The thickness of each of the second semiconductor layer 12 and the fifth semiconductor layer 15 is, for example, 10 nm or more and 5000 nm or less.

The thickness of each of the third semiconductor layer 13 and the sixth semiconductor layer 16 is, for example, 0.3 nm or more and 1000 nm or less.

Hereinafter, an example of a method for manufacturing the semiconductor light emitting device 110 will be described.

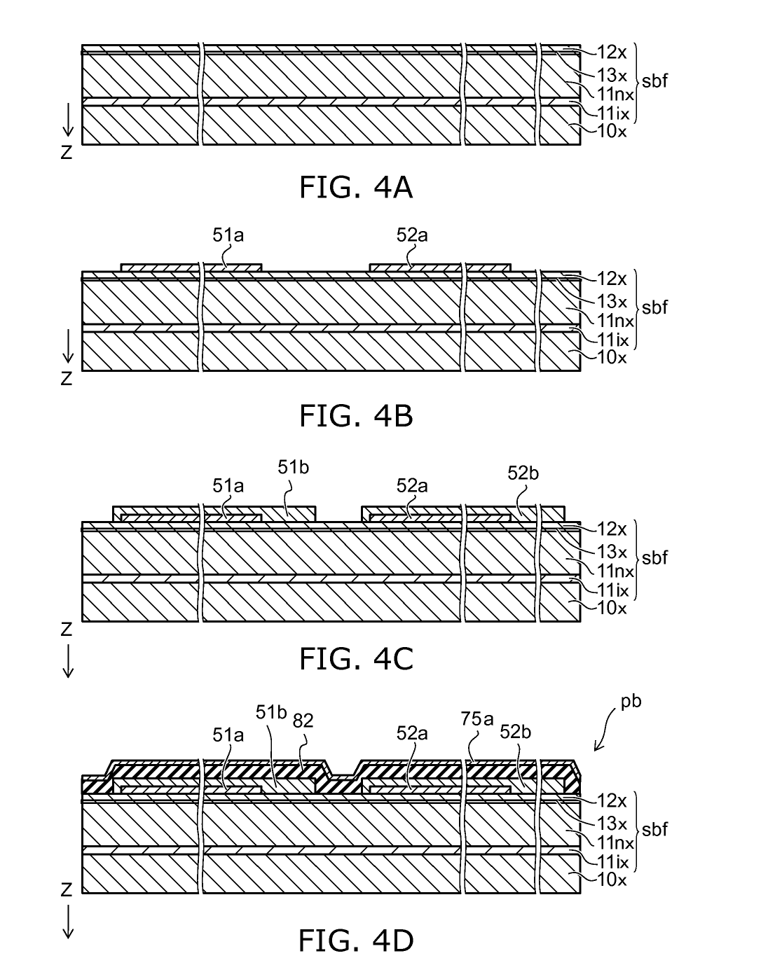

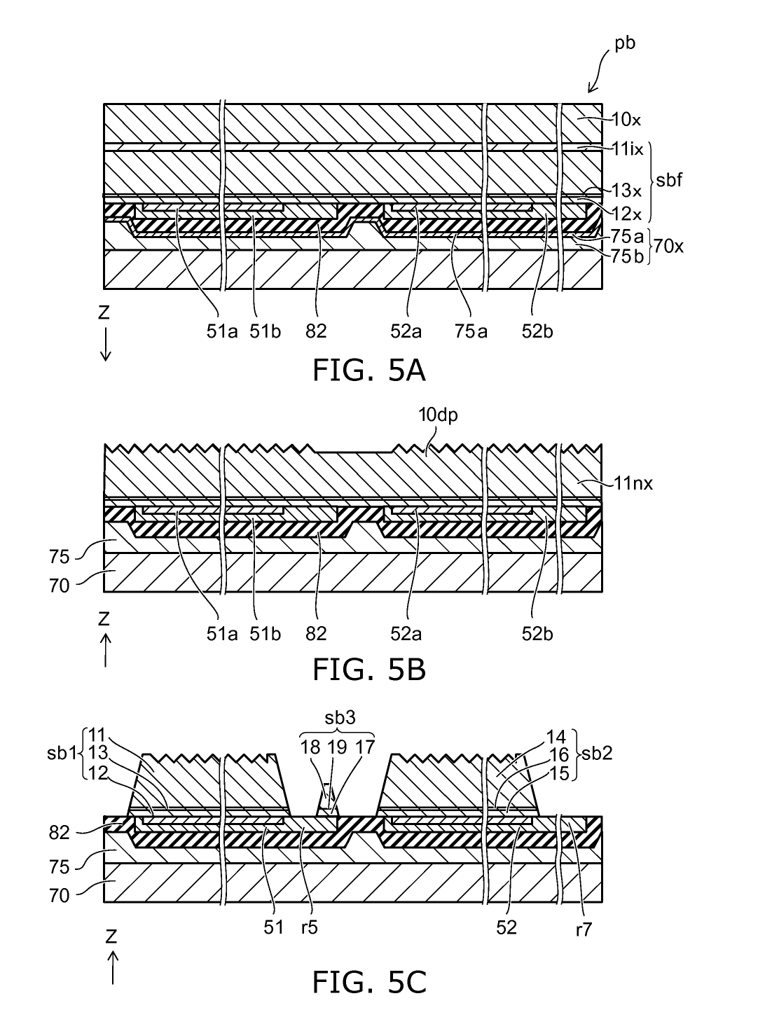

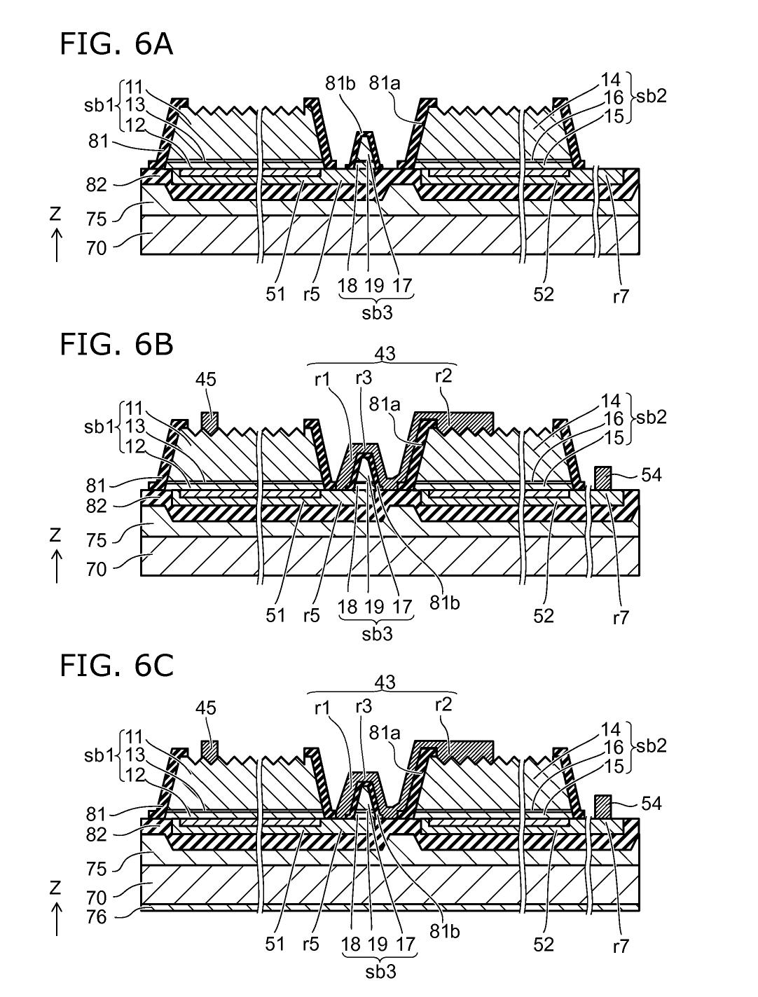

FIG. 4A to FIG. 4D, FIG. 5A to FIG. 5C, and FIG. 6A to FIG. 6C are schematic cross-sectional views illustrating, in the order of processes, the method for manufacturing the semiconductor light emitting device according to the first embodiment.

As shown in FIG. 4A, a low impurity concentration film 11ix is formed on a substrate 10x (growth substrate). The low impurity concentration film 11ix includes, for example, a buffer film (e.g., a stacked film of an Al-containing nitride semiconductor film, etc.). The low impurity concentration film 11ix may further include an undoped nitride semiconductor film (undoped GaN layer, etc.). An n-type semiconductor film 11nx is formed on the low impurity concentration film 11ix. The n-type semiconductor film 11nx serves as at least a portion of the first semiconductor layer 11 and at least a portion of the third semiconductor layer 13. At least a portion of the low impurity concentration film 11ix may serve as at least a portion of the first semiconductor layer 11 and at least a portion of the fourth semiconductor layer 14. A semiconductor film 13x is formed on the n-type semiconductor film 11nx. The semiconductor film 13x serves as the third semiconductor layer 13 and the sixth semiconductor layer 16. A semiconductor film 12x is formed on the semiconductor film 13x. The semiconductor film 12x serves as the second semiconductor layer 12 and the fifth semiconductor layer 15. Due to this, a stacked film sbf is obtained.

In the formation of these films, for example, epitaxial crystal growth is performed. For example, a metal-organic chemical vapor deposition (MOCVD) method, a metal-organic vapor phase epitaxy (MOVPE) method, a molecular beam epitaxy (MBE) method, a halide vapor phase epitaxy (HVPE) method, or the like is used.

For the substrate 10x, for example, a substrate of any of Si, SiO₂, A10₂, quartz, sapphire, GaN, SiC, and GaAs is used.

For the substrate 10x, a substrate obtained by combining them may be used. Any plane orientation of the substrate 10x may be employed.

As shown in FIG. 4B, the first metal layer 51a and the third metal layer 52a are formed on the semiconductor film 12x. These metal layers are, for example, silver films. The thickness of the silver film is, for example, about 200 nm (e.g., 150 nm or more and 250 nm or less). After the formation of the silver film, for example, heat treatment (sintering treatment) is performed in an atmosphere containing oxygen. The rate of oxygen in the atmosphere is, for example, 10% or more and 40% or less. The rate of an inert gas (e.g., nitrogen, etc.) in the atmosphere containing oxygen is 60% or more and 90% or less. The temperature of the heat treatment is, for example, about 400° C. (e.g., 350° C. or more and 450° C. or less).

As shown in FIG. 4C, the second metal layer 51b and the fourth metal layer 52b are formed on the first metal layer 51a, on the third metal layer 52a, and on the semiconductor film 12x. For example, as the second metal layer 51b and the fourth metal layer 52b, for example, a stacked film of Ni/Pt/Au/Ti is formed. The thickness of the stacked film is, for example, 0.7 μm.

For the formation of the first metal layer 51a, the second metal layer 51b, the third metal layer 52a, and the fourth metal layer 52b, for example, a vapor deposition method, a sputtering method, or the like is used. For the processing of these metal layers, for example, a lift-off method, wet etching, or the like is used.

As shown in FIG. 4D, the second insulating layer 82 is formed. As the second insulating layer 82, for example, a stacked film of silicon oxide film/silicon nitride film/silicon oxide film is formed.

Further, a metal film 75a serving as a portion of the fifth metal layer 75 is formed. Due to this, a processed body pb is formed.

For example, as the metal film 75a, a stacked film of first Ti film/Pt film/second Ti film/Ni film/Sn film is formed. The Pt film is formed on the first Ti film, the second Ti film is formed on the Pt film, the Ni film is formed on the second Ti film, and the Sn film is formed on the second Ti film. The thickness of the first Ti film is, for example, 5 nm or more and 20 nm or less (e.g., about 10 nm). The thickness of the Pt film is 50 nm or more and 200 nm or less (e.g., about 200 nm). The thickness of the second Ti film is 100 nm or more and 300 nm or less (e.g., about 200 nm). The thickness of the Ni film is 300 nm or more and 700 nm or less (e.g., about 500 nm). The thickness of the Sn film is 500 nm or more and 2000 nm or less (e.g., about 1000 nm).

As shown in FIG. 5A, a counter substrate 70x is prepared. The counter substrate 70x includes the base body 70 and a metal film 75b provided on the upper surface of the base body 70. As the metal film 75b, for example, a stacked film of Ti film/Pt film/Ti film/Ni film/Sn film is provided.

The processed body pb and the counter substrate 70x are disposed with the metal film 75a and the metal film 75b contacting each other. By heating in this state, the metal film 75a and the metal film 75b are melted and bonded together. The temperature of heating is, for example, 220° C. or more and 300° C. or less (e.g., about 280° C.). The time for heating is, for example, 3 minutes or more and 10 minutes or less (e.g., about 5 minutes). The metal film 75a and the metal film 75b form the fifth metal layer 75.

As shown in FIG. 5B, the substrate 10x is removed. For example, when the substrate 10x is a silicon substrate, grinding, dry etching (e.g., reactive ion etching (RIE)), or the like is used for the removal. For example, when the substrate 10x is a sapphire substrate, laser lift-off (LLO) or the like is used for the removal. In the embodiment, the low impurity concentration film 11ix may be removed. In this case, the surface of the n-type semiconductor film 11nx is exposed.

The corrugation 10dp are formed on the surface of the n-type semiconductor film 11nx. For example, the corrugation 10dp are formed by wet treatment using acid.

As shown in FIG. 5C, portions of the stacked film sbf are removed. For example, RIE, wet etching, or the like is used for the removal. The first stacked body sb1 and the second stacked body sb2 are obtained from the stacked film sbf. The structure sb3 is obtained from the stacked film sbf. That is, the first to ninth semiconductor layers 11 to 19 are formed. The fifth region r5 of the first conductive layer 51 and the seventh region r7 of the second conductive layer 52 are exposed.

As shown in FIG. 6A, for example, a silicon compound film (silicon oxide film, silicon nitride film, or silicon oxynitride film) serving as the insulating layer 81, the first insulating layer 81a, and the insulating layer 81b is formed by, for example, chemical vapor deposition (CVD). The thickness of the silicon compound film is, for example, about 400 nm (e.g., 100 nm or more and 1000 nm or less).

Portions of the silicon compound film are removed.

As shown in FIG. 6B, the fourth conductive layer 54, the fifth conductive layer 45, and the third conductive layer 43 are formed in regions exposed by the removal. For example, the fifth conductive layer 45 is formed on the first semiconductor layer 11. The fourth conductive layer 54 is formed on the seventh region r7 of the second conductive layer 52. The first region r1 of the third conductive layer 43 is disposed on the fifth region r5 of the first conductive layer 51. The second region r2 of the third conductive layer 43 is disposed on a portion of the fourth semiconductor layer 14. The third region r3 of the third conductive layer 43 is disposed on the structure sb3 (on the insulating layer 81b).

A wafer is cut in predetermined shapes. For example, a stacked body serving as a plurality of semiconductor light emitting devices is formed on one wafer, and the wafer is cut, so that the plurality of semiconductor light emitting devices are obtained. A passivation (the insulating layer 81, etc.) on a dicing street for cutting may be removed. Due to this, the crack of the passivation can be suppressed, so that yield is improved.

Treatment to reduce the thickness of the base body 70 (e.g., a silicon substrate) may be performed as necessary. For example, the thickness of the base body 70 is reduced to, for example, appropriately about 150 μm (e.g., 100 μm or more and 200 μm or less) by treatment such as grinding. The heat capacity can be further reduced.

As shown in FIG. 6C, the sixth metal layer 76 is formed on the lower surface of the base body 70. Due to this, the semiconductor light emitting device 110 is obtained.

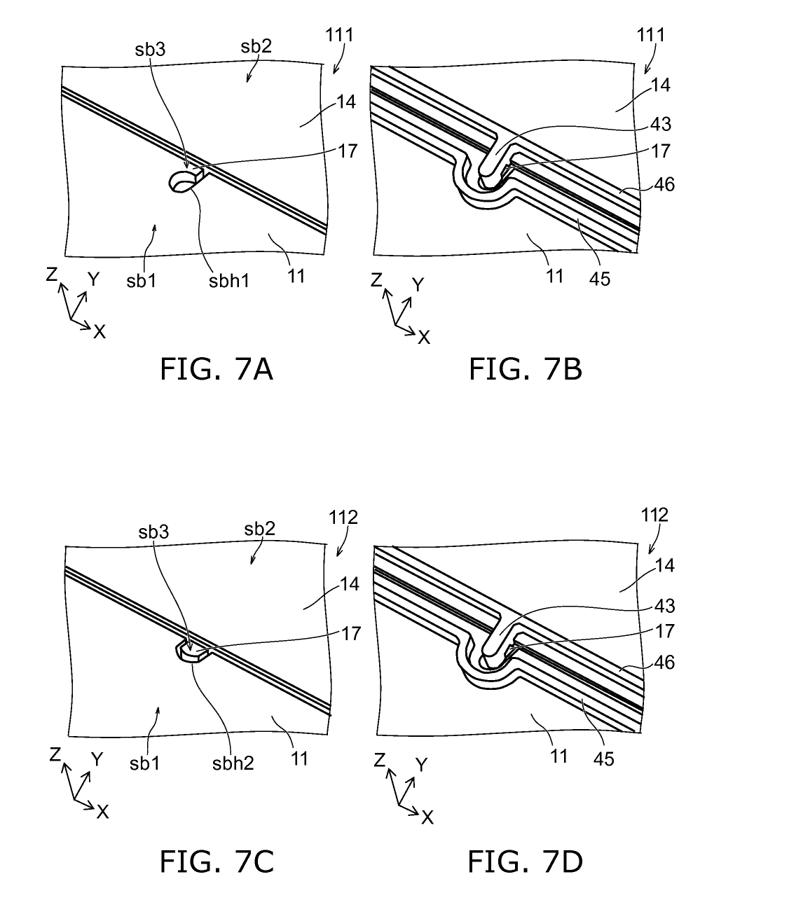

FIG. 7A to FIG. 7D are schematic perspective views illustrating portions of other semiconductor light emitting devices according to the first embodiment.

These drawings each show, in an enlarged manner, a portion corresponding to the portion AP shown in FIG. 1B. For the clarity of the drawings, FIG. 7A and FIG. 7C illustrate a state in which the fifth conductive layer 45 is removed. In these drawings, the insulating layers are omitted.

As shown in FIG. 7A and FIG. 7B, also in another semiconductor light emitting device 111 according to the embodiment, the structure sb3 is provided between the first stacked body sb1 and the second stacked body sb2. In this example, a concave portion sbh1 is provided in the semiconductor stacked film serving as the first stacked body sb1. A portion of the semiconductor stacked film between the concave portion sbh1 and the second stacked body sb2 serves as the structure sb3.

As shown in FIG. 7B, the fifth conductive layer 45 is provided on the semiconductor stacked film partially around the concave portion sbh1. One end (the first region r1) of the third conductive layer 43 is provided in the concave portion sbh1. The third region r3 of the third conductive layer 43 is provided on the semiconductor stacked film (the structure sb3) located between the concave portion sbh1 and the fourth semiconductor layer 14. The second region r2 of the third conductive layer 43 is provided on the fourth semiconductor layer 14.

Also in this case, the structure sb3 is continuous with the first stacked body sb1.

As shown in FIG. 7C and FIG. 7D, also in still another semiconductor light emitting device 112 according to the embodiment, the structure sb3 is provided between the first stacked body sb1 and the second stacked body sb2. In this example, the structure sb3 having an island shape is provided. That is, a groove sbh2 is provided between the structure sb3 and the first stacked body sb1, and the structure sb3 is divided from the first stacked body sb1.

As shown in FIG. 7D, the fifth conductive layer 45 is provided on the semiconductor stacked film partially around the groove sbh2 around the structure sb3 having an island shape. One end (the first region r1) of the third conductive layer 43 is provided in the groove sbh2. The third region r3 of the third conductive layer 43 is provided on the semiconductor stacked film (the structure sb3) located between the groove sbh2 and the fourth semiconductor layer 14. The second region r2 of the third conductive layer 43 is provided on the fourth semiconductor layer 14.

In this example, the structure sb3 is divided from the first stacked body sb1 and not continuous therewith.

In the embodiment as described above, the structure sb3 may be or may not be continuous with the first stacked body sb1.

### Second Embodiment

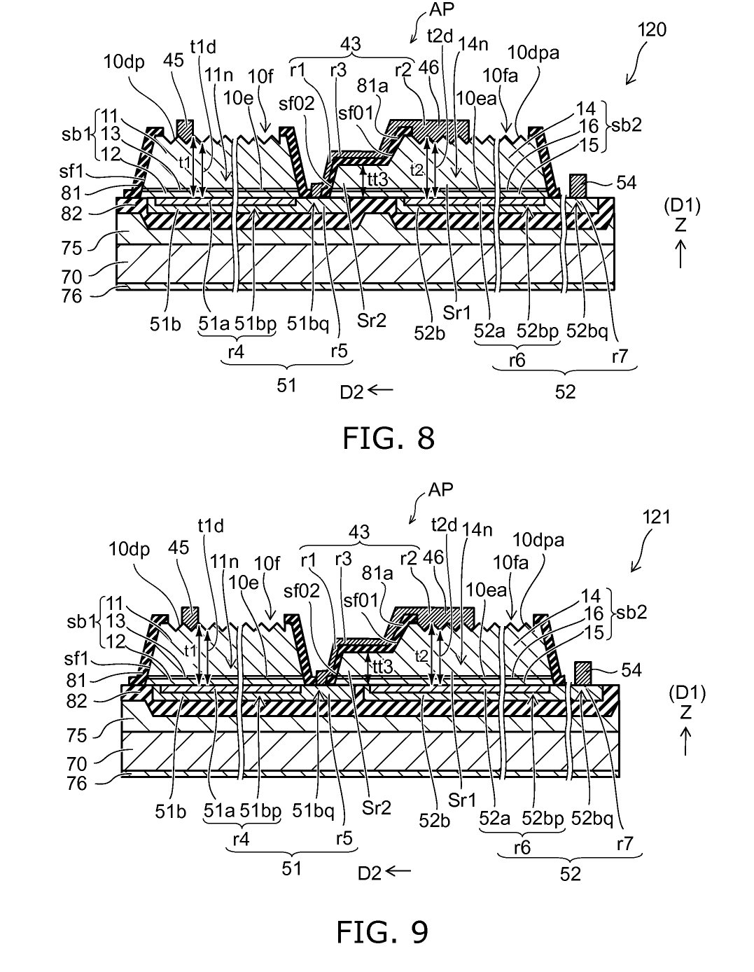

FIG. 8 is a schematic cross-sectional view illustrating a semiconductor light emitting device according to a second embodiment.

As shown in FIG. 8, the semiconductor light emitting device 120 according to the embodiment includes the base body 70, the first to sixth semiconductor layers 11 to 16, the first conductive layer 51, the second conductive layer 52, the third conductive layer 43, and the first insulating layer 81a. In the embodiment, the structure sb3 in the semiconductor light emitting device 110 is omitted, and the thickness of a portion of the second stacked body sb2 is reduced to provide the function of the structure sb3.

Also in this case, the first semiconductor layer 11 is separated from the base body 70 in the first direction D1. The first semiconductor layer 11 includes the first semiconductor film 11n of the first conductivity type. The second semiconductor layer 12 is provided between the first semiconductor layer 11 and the base body 70, and is of the second conductivity type. The third semiconductor layer 13 is provided between the first semiconductor layer 11 and the second semiconductor layer 12.

The first conductive layer 51 is electrically connected with the second semiconductor layer 12.

The fourth semiconductor layer 14 is separated from the base body 70 in the first direction D1, and arranged with the first semiconductor layer 11 in the second direction D2 (direction crossing the first direction D1). The fourth semiconductor layer includes the second semiconductor film 14n of the first conductivity type. The fourth semiconductor layer 14 includes a first semiconductor region sr1 and a second semiconductor region sr2. The second semiconductor region sr2 is provided between at least a portion of the first semiconductor region sr1 and at least a portion of the first semiconductor layer 11.

The fifth semiconductor layer 15 is provided between the fourth semiconductor layer 14 and the base body 70, and is of the second conductivity type. The sixth semiconductor layer 16 is provided between the fourth semiconductor layer 14 and the fifth semiconductor layer 15. The sixth semiconductor layer 16 is, for example, a light emitting layer.

The second conductive layer 52 is electrically connected with the fifth semiconductor layer 15.

The third conductive layer 43 is electrically connected with the fourth semiconductor layer 14. Specifically, the third conductive layer 43 is electrically connected with the second semiconductor film 14n. The third conductive layer 43 includes the first region r1, the second region r2, and the third region r3. The third region r3 is provided between the first region r1 and the second region r2. The first to third regions r1 to r3 are first to third conductive regions.

At least a portion of the first insulating layer 81a is provided between the third conductive layer 43 and the fifth semiconductor layer 15.

The fourth region r4 of the first conductive layer 51 is provided between the second semiconductor layer 12 and the base body 70.

The fifth region r5 of the first conductive layer 51 is provided between the first region r1 of the third conductive layer 43 and the base body 70. The fifth region r5 is electrically connected with the first region r1.

The first semiconductor region sr1 of the fourth semiconductor layer 14 is provided between the second region r2 of the third conductive layer 43 and the second conductive layer 52. The second semiconductor region sr2 of the fourth semiconductor layer 14 is provided between the third region r3 of the third conductive layer 43 and the base body 70. In this example, the second conductive layer 52 is provided between the first semiconductor region sr1 of the fourth semiconductor layer 14 and the base body 70, and is not provided between the second semiconductor region sr2 of the fourth semiconductor layer 14 and the base body 70.

A total thickness tt3 (length along the first direction D1) of the second semiconductor region sr2, the fifth semiconductor layer 15, and the sixth semiconductor layer 16 is smaller than the distance t2 between the second region r2 and the second conductive layer 52 along the first direction D1. The thickness tt3 is thinner than a total thickness (e.g., corresponding to the distance t2) of the first semiconductor region sr1, the fifth semiconductor layer 15, and the sixth semiconductor layer 16.

That is, the second semiconductor region sr2 is thinner than the first semiconductor region sr1. For example, the height of the upper surface of the second semiconductor region sr2 is lower than the height of the upper surface of the first semiconductor region sr1 based on the base body 70.

The third conductive layer 43 reaches, from a region on the fifth region r5 of the first conductive layer 51 through a region above the second semiconductor region sr2, a region on the first semiconductor region sr1. By providing the second semiconductor region sr2 with a low height in the middle, for example, the disconnection of the third conductive layer 43 or the like is suppressed. The electrical connection becomes stable. For this reason, the design tolerance taking the disconnection into consideration is increased. For example, the gap between the plurality of LEDs can be reduced, so that luminous efficiency can be improved. Further, high reliability is obtained. Further, yield is improved, so that high productivity is obtained.

In the semiconductor light emitting device 120, the side surface of the fourth semiconductor layer 14 is favorably inclined (tapered). That is, the first semiconductor region sr1 includes a side surface sf01 crossing the second direction D2 and inclined to the first direction D1. The second semiconductor region sr2 includes a side surface sf02 crossing the second direction D2 and inclined to the first direction D1. Due to this, the disconnection or the like is more reliably suppressed.

The first insulating layer 81a extends between the third conductive layer 43 and the side surface sf01 of the first semiconductor region sr1. The first insulating layer 81a extends between the third conductive layer 43 and the side surface sf02 of the second semiconductor region sr2.

In the embodiment, the thickness tt3 is favorably ⅕ times or more and ⅔ times or less the distance t2. When the thickness tt3 is excessively thin, the disconnection of the third conductive layer 43 may be likely to occur between the second semiconductor region sr2 and the first semiconductor region sr1. When the thickness tt3 is excessively thick, the disconnection of the third conductive layer 43 may be likely to occur between the first conductive layer 51 and the second semiconductor region sr2.

The semiconductor light emitting device 120 can be configured similarly to the semiconductor light emitting device 110 except for those described above, and therefore, the description is omitted.

FIG. 9 is a schematic cross-sectional view illustrating another semiconductor light emitting device according to the second embodiment.

As shown in FIG. 9, in the semiconductor light emitting device 121 according to the embodiment, a portion of the second conductive layer 52 is provided between a portion (at least a portion) of the second semiconductor region sr2 of the fourth semiconductor layer 14 and the base body 70. Except for this, the semiconductor light emitting device 121 is similar to the semiconductor light emitting device 120, and therefore, the description is omitted.

Also in the semiconductor light emitting device 121, for example, the disconnection of the third conductive layer 43 or the like can be suppressed, so that the electrical connection becomes stable. The design tolerance taking the disconnection into consideration is increased, so that luminous efficiency can be improved. Further, high reliability is obtained. Further, yield is improved, so that high productivity is obtained.

### Third Embodiment

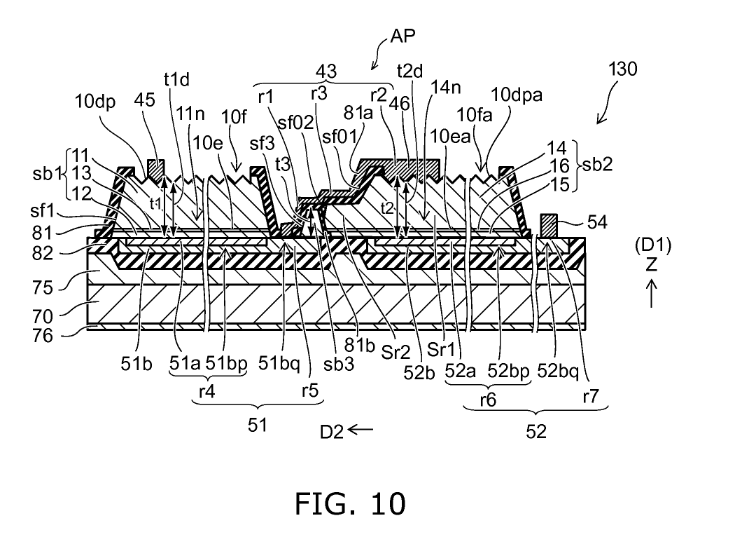

FIG. 10 is a schematic cross-sectional view illustrating a semiconductor light emitting device according to a third embodiment.

As shown in FIG. 10, in the semiconductor light emitting device 130 according to the embodiment, the structure sb3 is provided, and the first semiconductor region sr1 and the second semiconductor region sr2 are provided in the fourth semiconductor layer 14. The structure sb3 and the second semiconductor region sr2 are provided between the third region r3 of the third conductive layer 43 and the base body 70. At least a portion of the second semiconductor region sr2 is provided between at least a portion of the first semiconductor region sr1 and at least a portion of the structure sb3. In this manner, both the structure sb3 according to the first embodiment and the second semiconductor region sr2 according to the second embodiment may be provided. Also in this case, the disconnection of the third conductive layer 43 or the like can be suppressed, so that the electrical connection becomes stable. The design tolerance taking the disconnection into consideration is increased, and luminous efficiency can be improved. Further, high reliability is obtained. Further, yield is improved, so that high productivity is obtained.

In a configuration in which a plurality of LEDs are connected in series, a thermal resistance is high in a reference example in which the plurality of LEDs are connected in series on an insulating growth substrate of sapphire or the like, and therefore, the reference example has a problem of heat dissipation property. In the embodiment, the growth substrate is removed, so that the heat capacity is small. The conductive base body 70 is used, so that the thermal resistance is low. At least any of the structure sb3 and the second semiconductor region sr2 is used, so that the disconnection can be suppressed. A plurality of devices are connected by means of a plurality of interconnections, so that a region covered by the interconnection can be reduced.

According to the embodiments, it is possible to provide a semiconductor light emitting device capable of improving efficiency.

In the specification, “nitride semiconductor” includes all compositions of semiconductors of the chemical formula BₓIn_{y}Al_{z}Ga_{1-x-y-z}N (0≦x≦1, 0≦y≦1, 0≦z≦1, and x+y+z≦1) for which the composition ratios x, y, and z are changed within the respective ranges. “Nitride semiconductor” further includes group V elements other than N (nitrogen) in the chemical formula described above, various elements added to control various properties such as the conductivity type, and various elements included unintentionally.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in semiconductor light emitting devices such as semiconductor layers, conductive layers, metal layers, insulating layers, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor light emitting devices practicable by an appropriate design modification by one skilled in the art based on the semiconductor light emitting devices described above as embodiments of the invention also are within the scope of the invention to the extent that the spirit of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor light emitting device comprising:
a base body;
a first semiconductor layer separated from the base body in a first direction and including a first semiconductor film of a first conductivity type;
a second semiconductor layer of a second conductivity type provided between the first semiconductor layer and the base body;
a third semiconductor layer provided between the first semiconductor layer and the second semiconductor layer;
a first conductive layer electrically connected with the second semiconductor layer;
a fourth semiconductor layer separated from the base body in the first direction, arranged with the first semiconductor layer in a second direction crossing the first direction, and including a second semiconductor film of the first conductivity type;
a fifth semiconductor layer of the second conductivity type provided between the fourth semiconductor layer and the base body;
a sixth semiconductor layer provided between the fourth semiconductor layer and the fifth semiconductor layer;
a second conductive layer electrically connected with the fifth semiconductor layer;
a structure separated from the base body in the first direction, at least a portion of the structure being provided between the first semiconductor layer and the fourth semiconductor layer;
a third conductive layer electrically connected with the fourth semiconductor layer, the third conductive layer including a first region, a second region, and a third region between the first region and the second region; and
a first insulating layer, at least a portion of the first insulating layer being provided between the third conductive layer and the fifth semiconductor layer,
a fourth region of the first conductive layer being provided between the second semiconductor layer and the base body,
a fifth region of the first conductive layer being provided between the first region and the base body, the fifth region being electrically connected with the first region,
a portion of the fourth semiconductor layer being provided between the second region and the second conductive layer,
the structure being provided between the third region and the base body,
a thickness of the structure along the first direction being smaller than a distance between the second region and the second conductive layer along the first direction.

2. The device according to claim 1, wherein
a stacked body including the fourth semiconductor layer, the sixth semiconductor layer, and the fifth semiconductor layer includes a side surface crossing the second direction and inclined to the first direction.

3. The device according to claim 2, wherein
the first insulating layer extends between the third conductive layer and the side surface.

4. The device according to claim 1, wherein
a side surface of the structure crossing the second direction is inclined to the first direction.

5. The device according to claim 1, wherein
the thickness is ⅕ times or more and ⅔ times or less the distance.

6. The device according to claim 1, wherein
the structure includes
a seventh semiconductor layer of the first conductivity type,
an eighth semiconductor layer of the second conductivity type provided between the seventh semiconductor layer and the base body, and
a ninth semiconductor layer provided between the seventh semiconductor layer and the eighth semiconductor layer.

7. A semiconductor light emitting device comprising:
a base body;
a first semiconductor layer separated from the base body in a first direction and including a first semiconductor film of a first conductivity type;
a second semiconductor layer of a second conductivity type provided between the first semiconductor layer and the base body;
a third semiconductor layer provided between the first semiconductor layer and the second semiconductor layer;
a first conductive layer electrically connected with the second semiconductor layer;
a fourth semiconductor layer separated from the base body in the first direction, arranged with the first semiconductor layer in a second direction crossing the first direction, and including a second semiconductor film of the first conductivity type, the fourth semiconductor layer including a first semiconductor region and a second semiconductor region, the second semiconductor region being provided between at least a portion of the first semiconductor region and at least a portion of the first semiconductor layer;
a fifth semiconductor layer of the second conductivity type provided between the fourth semiconductor layer and the base body;
a sixth semiconductor layer provided between the fourth semiconductor layer and the fifth semiconductor layer;
a second conductive layer electrically connected with the fifth semiconductor layer;
a third conductive layer electrically connected with the fourth semiconductor layer, the third conductive layer including a first region, a second region, and a third region between the first region and the second region; and
a first insulating layer, at least a portion of the first insulating layer being provided between the third conductive layer and the fifth semiconductor layer,
a fourth region of the first conductive layer being provided between the second semiconductor layer and the base body,
a fifth region of the first conductive layer being provided between the first region and the base body, the fifth region being electrically connected with the first region,
the first semiconductor region being provided between the second region and the second conductive layer,
the second semiconductor region being provided between the third region and the base body,
a total thickness of the second semiconductor region, the fifth semiconductor layer, and the sixth semiconductor layer being smaller than a distance between the second region and the second conductive layer along the first direction.

8. The device according to claim 7, wherein
the first semiconductor region includes a side surface crossing the second direction and inclined to the first direction.

9. The device according to claim 8, wherein
the first insulating layer extends between the third conductive layer and the side surface of the first semiconductor region.

10. The device according to claim 7, wherein
the second semiconductor region includes a side surface crossing the second direction and inclined to the first direction.

11. The device according to claim 10, wherein
the first insulating layer extends between the third semiconductor layer and the side surface of the second semiconductor region.

12. The device according to claim 7, wherein
the thickness is ⅕ times or more and ⅔ times or less the distance.

13. The device according to claim 1, wherein
the first conductive layer includes a first metal layer and a second metal layer,
the first metal layer is provided between the second semiconductor layer and the base body,
a first portion of the second metal layer is provided between the first metal layer and the base body, and
a second portion of the second metal layer is provided between the first region and the base body.

14. The device according to claim 1, wherein
the second conductive layer includes a third metal layer and a fourth metal layer,
the third metal layer is provided between the fifth semiconductor layer and the base body, and
a third portion of the fourth metal layer is provided between the third metal layer and the base body.

15. The device according to claim 14, further comprising a fourth conductive layer,
a fourth portion of the fourth metal layer being disposed between the fourth conductive layer and the base body, and
the fourth conductive layer being electrically connected with the fourth portion.

16. The device according to claim 1, further comprising a fifth conductive layer,
the first semiconductor layer being disposed between the fifth conductive layer and the base body, and
the fifth conductive layer being electrically connected with the first semiconductor film.

17. The device according to claim 1, further comprising a second insulating layer provided between the first conductive layer and the base body and between the second conductive layer and the base body.

18. The device according to claim 17, wherein
the base body is conductive.

19. The device according to claim 17 or 18, further comprising a fourth metal layer provided between the second insulating layer and the base body.

20. The device according to claim 17, further comprising a sixth metal layer,
the base body being disposed between the second insulating layer and the sixth metal layer.
